(19) United States
(12) Patent Application Publication
(10) Pub. No.: US 2026/0125799 A1
(43) Pub. Date: May 7, 2026

(54) FILM FORMING METHOD AND FILM FORMING APPARATUS

(71) Applicant: Tokyo Electron Limited, Tokyo (JP)

(72) Inventors: Yumiko KAWANO, Nirasaki City (JP); Shuji AZUMO, Nirasaki City (JP)

(21) Appl. No.: 19/427,446

(22) Filed: Dec. 19, 2025

Related U.S. Application Data
(63) Continuation of application No. PCT/JP2024/021817, filed on Jun. 17, 2024.

(30) Foreign Application Priority Data
Jun. 28, 2023 (JP) 2023-105828
May 8, 2024 (JP) 2024-075701

(51) Int. Cl. C23C 16/56; C23C 16/04; C23C 16/40; C23C 16/455; C23C 16/458; C23C 16/52

(52) U.S. Cl. CPC C23C 16/56; C23C 16/04; C23C 16/401; C23C 16/403; C23C 16/45544; C23C 16/4583; C23C 16/52

(57) ABSTRACT

A film forming method includes: (A) preparing a substrate having first and second films on different regions of a surface of the substrate; (B) selectively forming a film formation inhibiting film inhibiting formation of a target film on the second film with respect to the first film; (C) selectively forming the target film on the first film with respect to the second film using the film formation inhibiting film; and (D) preferentially etching a part with respect to another part of the target film, wherein (D) includes: (Da) supplying a fluorine-containing gas to a surface of the target film to adsorb fluorine or form a fluorine-containing layer on the surface thereof, (Db) after (Da), supplying a H₂O gas to the surface of the target film to generate hydrogen fluoride; and (Dc) after (Db), supplying a plasma-activated gas to the surface of the target film.

### CROSS-REFERENCE TO RELATED APPLICATIONS

This application is a Bypass Continuation Application of PCT International Application No. PCT/JP2024/021817, filed on Jun. 17, 2024 and designating the United States, the international application being based upon and claiming the benefit of priorities from Japanese Patent Application No. 2023-105828, filed on Jun. 28, 2023, and Japanese Patent Application No. 2024-075701, filed on May 8, 2024, the entire contents of which are incorporated herein by reference.

### TECHNICAL FIELD

The present disclosure relates to a film forming method and a film forming apparatus.

### BACKGROUND

A film forming method described in Patent Document 1 includes the following (1) to (4): (1) preparing a substrate having, on a surface thereof, a first region in which a first film is exposed and a second region in which a second film formed of a material different from that of the first film is exposed; (2) selectively forming a self-assembled monolayer in the second region, among the first and second regions by supplying, to the surface of the substrate, an organic compound containing fluorine serving as a precursor of the self-assembled monolayer; (3) forming a target film in the first region while inhibiting formation of the target film in the second region by using the self-assembled monolayer; and (4) etching an end of the target film protruding from the first region by supplying a gas containing H₂O to the surface of the substrate.

An etching method described in Patent Document 2 includes: modifying a silicon oxide film to generate a reaction product by supplying a mixed gas of a hydrogen fluoride (HF) gas and an ammonia (NH₃) gas to a surface of the silicon oxide film; and removing the reaction product by heating. An etching method described in Patent Document 3 includes: forming an etching product composed of ammonium fluorosilicate salt by a reaction between an oxide film and one or more gases selected from the group of NF₃, H₂, N₂, HF, and NH₃; and sublimating the etching product at a temperature of 100 degrees C. or higher.

### PRIOR ART DOCUMENTS

### Patent Documents

Patent Document 1: Japanese Laid-open Publication No. 2022-055462
Patent Document 2: Japanese Laid-open Publication No. 2007-180418
Patent Document 3: Japanese Laid-open Publication No. 2009-140944

### SUMMARY

A film forming method according to an aspect of the present disclosure includes the following (A) to (D):
(A) preparing a substrate having a first film and a second film formed of a material different from that of the first film on different regions of a surface of the substrate;
(B) selectively forming a film formation inhibiting film that inhibits formation of a target film on a surface of the second film with respect to a surface of the first film;
(C) selectively forming the target film on the surface of the first film with respect to the surface of the second film by using the film formation inhibiting film; and
(D) preferentially etching a part of the target film with respect to another part of the target film,
wherein (D) includes:
(Da) supplying a fluorine-containing gas to a surface of the target film to adsorb fluorine on the surface of the target film, or to form a fluorine-containing layer on the surface of the target film;
(Db) after (Da), supplying a H₂O gas to the surface of the target film to generate hydrogen fluoride; and
(Dc) after (Db), supplying a plasma-activated gas to the surface of the target film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to one embodiment.

FIG. 2 is a flowchart illustrating one example of a subroutine of S105.

FIG. 3 is a flowchart illustrating one example of a subroutine of S106.

FIG. 4A is a cross-sectional view illustrating a first example of S101.

FIG. 4B is a cross-sectional view illustrating a first example of S102 and S103.

FIG. 4C is a cross-sectional view illustrating a first example of S104.

FIG. 4D is a cross-sectional view illustrating a first example of S105.

FIG. 4E is a cross-sectional view illustrating a first example of S106a.

FIG. 4F is a cross-sectional view illustrating a first example of S106b and S106c.

FIG. 5A is a cross-sectional view illustrating a second example of S101.

FIG. 5B is a cross-sectional view illustrating a second example of S102 and S103.

FIG. 5C is a cross-sectional view illustrating a second example of S104.

FIG. 5D is a cross-sectional view illustrating a second example of S105.

FIG. 5E is a cross-sectional view illustrating a second example of S106a.

FIG. 5F is a cross-sectional view illustrating a second example of S106b and S106c.

FIG. 6A is a cross-sectional view illustrating a third example of S101.

FIG. 6B is a cross-sectional view illustrating a third example of S102 and S103.

FIG. 6C is a cross-sectional view illustrating a third example of S104.

FIG. 6D is a cross-sectional view illustrating a third example of S105.

FIG. 6E is a cross-sectional view illustrating a third example of S106a.

FIG. 6F is a cross-sectional view illustrating a third example of S106b and S106c.

FIG. 7 is a plan view illustrating a film forming apparatus according to one embodiment.

FIG. 8 is a cross-sectional view illustrating an example of a first processing section of FIG. 7.

FIG. 9 is a diagram illustrating a relationship between a gas supply time and an etching amount of a SiO film in S106a of Examples 10 to 13.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In addition, in each drawing, the same reference numerals will be given to the same or corresponding components, and descriptions thereof may be omitted.

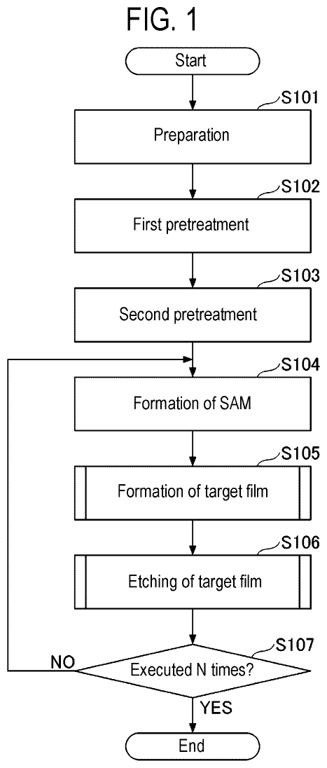

A film forming method according to one embodiment will be described mainly with reference to FIGS. 1 to 6F. The film forming method includes steps S101 to S107 illustrated in FIG. 1, for example. In addition, the film forming method may include at least steps S101 and S104 to S107, and may not include steps S102 and S103. Further, the film forming method may include steps other than steps S101 to S107 illustrated in FIG. 1.

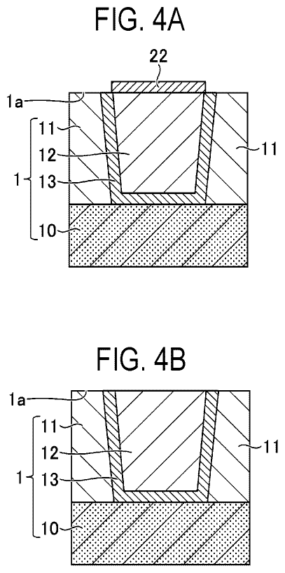

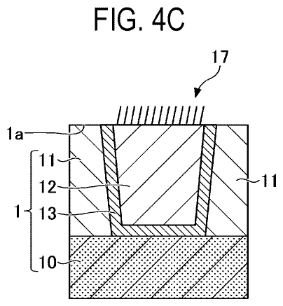

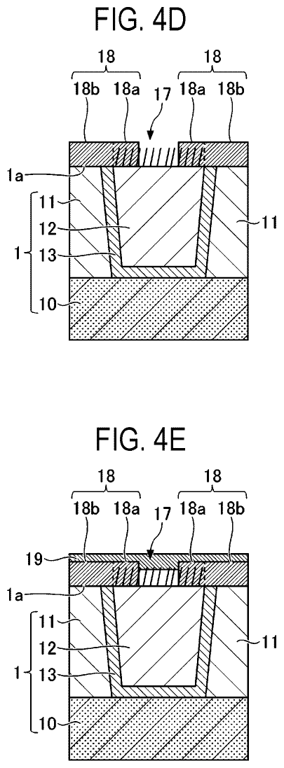

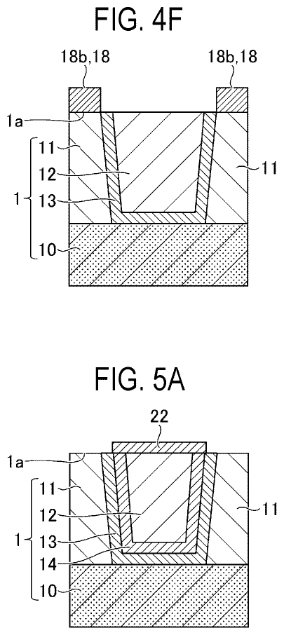

Step S101 includes preparing a substrate 1, as illustrated in FIG. 4A. The substrate 1 includes an underlying substrate 10. The underlying substrate 10 is, for example, a silicon wafer, a compound semiconductor wafer, or a glass substrate. The substrate 1 includes an insulating film 11 and a conductive film 12 in different regions of a substrate surface 1 a. The substrate surface 1a is, for example, an upper surface of the substrate 1. The insulating film 11 and the conductive film 12 are formed on the underlying substrate 10. Another functional film may be formed between the underlying substrate 10 and the insulating film 11 or between the underlying substrate 10 and the conductive film 12. The insulating film 11 is an example of a first film, and the conductive film 12 is an example of a second film. In addition, materials of the first and second films are not particularly limited.

The insulating film 11 is, for example, an interlayer insulating film. The interlayer insulating film is desirably a low dielectric constant (Low-k) film. The insulating film 11 is not particularly limited, but is, for example, a SiO film, a SiN film, a SiOC film, a SiON film, or a SiOCN film. Here, the SiO film refers to a film containing silicon (Si) and oxygen (O). An atomic ratio of Si to O in the SiO film is usually 1:2, but is not limited to 1:2. Similarly, the SiN film, the SiOC film, the SiON film, and the SiOCN film each mean a film containing respective elements, and are not limited to a stoichiometric ratio. The insulating film 11 has a recess on the substrate surface 1a. The recess is a trench, a contact hole, or a via hole.

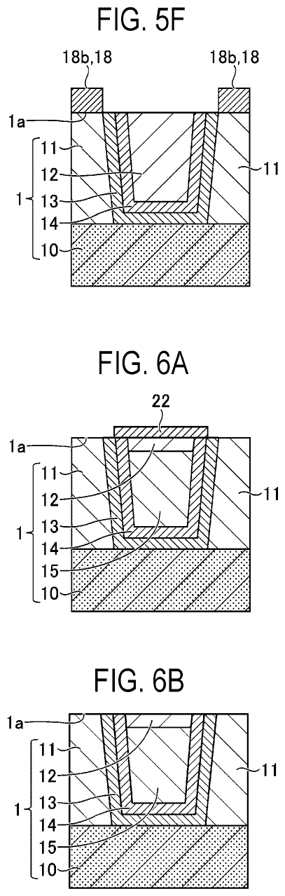

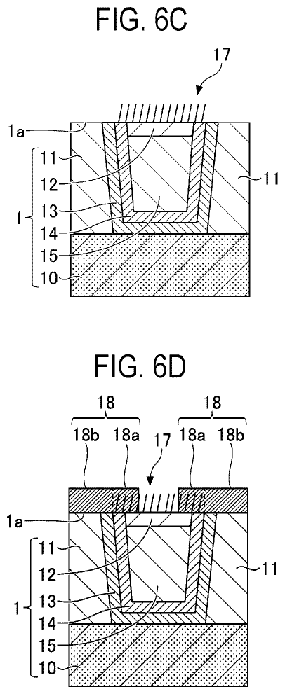

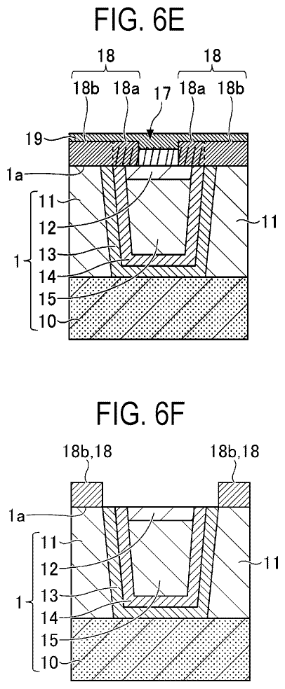

For example, the recess of the insulating film 11 is filled with the conductive film 12. The conductive film 12 is, for example, a metal film. The metal film is, for example, a Cu film, a Co film, a Ru film, a W film, or a Mo film. In addition, the conductive film 12 may also be a cap film. Specifically, as illustrated in FIG. 6A, a second conductive film 15 may be embedded in the recess of the insulating film 11, and the conductive film 12 may cover the second conductive film 15. The second conductive film 15 is formed of a metal different from that of the conductive film 12. For example, the second conductive film 15 is a Cu film, and the conductive film 12 (cap film) is a Co film or a Ru film.

The substrate 1 may further include a third film on the substrate surface 1a. The third film is, for example, a barrier film 13. The barrier film 13 is formed between the insulating film 11 and the conductive film 12 to prevent metal diffusion from the conductive film 12 into the insulating film 11. The barrier film 13 is not particularly limited, but is, for example, a TaN film or TiN film. Here, the TiN film means a film containing titanium (Ti) and nitrogen (N). An atomic ratio of Ti to N in the TiN film is usually 1:1, but is not limited to 1:1. Similarly, the TaN film means a film containing respective elements, and is not limited to a stoichiometric ratio.

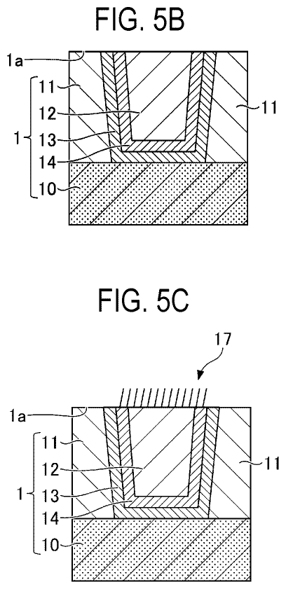

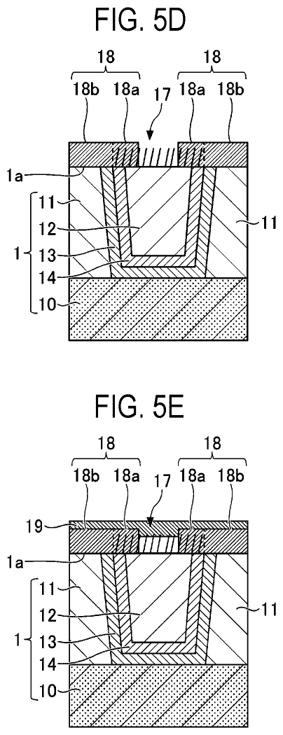

The substrate 1 may further include a fourth film on the substrate surface 1a. The fourth film is, for example, a liner film 14 (see FIGS. 5A and 6A). The liner film 14 is formed between the conductive film 12 and the barrier film 13. The liner film 14 is formed on the barrier film 13 and assists in the formation of the conductive film 12. The conductive film 12 is formed on the liner film 14. For example, the conductive film 12 is a Cu film, and the liner film 14 is a Co film or a Ru film.

As illustrated in FIGS. 4A, 5A, and 6A, a contaminant 22 may be present on the substrate surface 1a. The contaminant 22 is, for example, a metal oxide. The metal oxide is formed, for example, by a reaction between the conductive film 12 and the atmosphere. The contaminant 22 may also be an organic matter. The organic matter is, for example, a carbon-containing deposit adhering in the course of processing the substrate 1. The organic matter may be layered.

Step S102 includes performing a first pretreatment to remove the contaminant 22 on the substrate surface 1a, as illustrated in FIGS. 4B, 5B, and 6B. In the first pretreatment, a cleaning gas is supplied to the substrate surface 1a. Multiple cleaning gases may be supplied sequentially. In the present embodiment, a first cleaning gas, a second cleaning gas, and a third cleaning gas are supplied in this order.

The first cleaning gas includes at least a reducing gas such as H₂ gas, and may further include a nitrogen-containing gas such as N₂ gas, in addition to the reducing gas. The first cleaning gas is desirably supplied to the substrate surface 1a after being plasma-activated.

An example of a processing condition of the first cleaning gas is illustrated below:
H₂ gas flow rate: 50 sccm to 5,000 sccm;
N₂ gas flow rate: 50 sccm to 10,000 sccm;
Ar gas flow rate: 20 sccm to 10,000 sccm;
Proportion of H₂ gas in the first cleaning gas: 10 vol % to 60 vol %;
Proportion of N₂ gas in the first cleaning gas: 10 vol % to 80 vol %;
Power supply frequency for plasma generation: 10 MHz to 100 MHz;
Power for plasma generation: 50 W to 400 W;
Processing time: 5 seconds to 120 seconds;
Processing temperature (substrate temperature): 80 degrees C. to 350 degrees C.; and
Processing pressure: 50 Pa to 2,000 Pa.

The second cleaning gas includes an oxygen-containing gas. The oxygen-containing gas includes at least one selected from the group of an O₂ gas, an O₃ gas, a H₂O gas, a NO gas, a NO₂ gas, and a N₂O gas. The oxygen-containing gas is supplied to the substrate surface 1a without being plasma-activated.

An example of a processing condition using the second cleaning gas is illustrated below:
O₂ gas flow rate: 100 sccm to 2,000 sccm;
Processing time: 10 seconds to 5 minutes;
Processing temperature (substrate temperature): 80 degrees C. to 350 degrees C.; and
Processing pressure: 50 Pa to 665 Pa.

The third cleaning gas includes, for example, at least one selected from the group of a carboxylic acid-based compound, a phosphonic acid-based compound, a nitro-based compound, and a thiol-based compound. The carboxylic acid-based compound is represented by a general formula “R—COOH.” The phosphonic acid-based compound is represented by a general formula “R—P(═O)(OH)₂.” The nitro-based compound is represented by a general formula “R—NO₂.” The thiol-based compounds is represented by a general formula “R—SH.”

In these general formulas, R is, for example, a hydrocarbon group, or a hydrocarbon group in which at least part of hydrogen is substituted with fluorine. Specifically, R is, for example, “CF₃—(CF₂)ₓ—,” “CF₃—(CF₂)ₓ—CH₂—CH₂—,” or “CH₃—(CH₂)ₓ—.” Herein, x is an integer of 1 to 17. Specific examples of the carboxylic acid-based compound may include PFBA(CF₃(CF₂)₂COOH), formic acid (HCOOH), acetic acid (CH₃COOH), propionic acid (CH₃CH₂COOH), and octanoic acid (CH₃(CH₂)₆COOH). Specific examples of the nitro-based compound may include PFNO(CF₃(CF₂)₅CH₂CH₂NO₂).

An example of a processing condition of the third cleaning gas is illustrated below:
PFBA gas flow rate: 10 sccm to 100 sccm;
Processing time: 30 seconds to 10 minutes;
Processing temperature (substrate temperature): 80 degrees C. to 350 degrees C.; and
Processing pressure: 100 Pa to 300 Pa.

Step S103 includes performing a second pretreatment to remove a residue of the cleaning gas supplied in step S102. The residue of the cleaning gas is mainly an organic matter. In the second pretreatment, a plasma-activated gas is supplied to the substrate surface 1a. The gas includes at least a reducing gas such as H₂ gas, and may further include a nitrogen-containing gas such as N₂ gas, in addition to the reducing gas. The processing condition of step S103 is the same as the processing condition using the first cleaning gas in step S102, and therefore, description thereof will be omitted.

Step S104 includes selectively forming a self-assembled monolayer 17 on the surface of the conductive film 12 with respect to the surface of the insulating film 11, as illustrated in FIGS. 4C, 5C, and 6C. Hereinafter, the self-assembled monolayer (SAM) 17 may also be referred to as the “SAM 17.” The SAM 17 is formed by supplying an organic compound gas to the substrate surface 1a. The organic compound gas is a precursor gas of the SAM 17.

The precursor gas of the SAM 17 is not particularly limited, but includes, for example, a thiol-based compound. Specific examples of the thiol-based compound may include CF₃(CF₂)₅CH₂CH₂SH(1H, 1H, 2H, 2H-perfluorooctanethiol: PFOT) and CH₃(CH₂)₅SH(Hexanethiol: HT). The thiol-based compound is more easily chemisorbed on the surface of the conductive film 12 than on the surface of the insulating film 11. Therefore, the SAM 17 is selectively formed on the surface of the conductive film 12 with respect to the surface of the insulating film 11. The SAM 17 is hardly formed on the surface of the insulating film 11. As illustrated in FIGS. 5C and 6C, the SAM 17 may be formed not only on the surface of the conductive film 12 but also on the surface of the liner film 14.

The precursor gas of the SAM 17 is not limited to the thiol-based compound. The precursor gas of the SAM 17 may include a phosphonic acid-based compound, a carboxylic acid-based compound, or a nitro-based compound. The third cleaning gas and the precursor gas of the SAM 17 may contain the same organic compound or different organic compounds, but desirably contain the same organic compound. By using the same organic compound, the number of chambers to be used may be reduced, thereby reducing cost.

In addition, the precursor gas of the SAM 17 may also contain an olefin-based compound or an organosilane-based compound. The olefin-based compound is represented by a general formula “R—CH═CH₂.” The organosilane-based compound is, for example, a trichlorosilane-based compound, a methoxysilane-based compound, or an ethoxysilane-based compound. The trichlorosilane-based organic compound is represented by a general formula “R—SiCl₃.” The methoxysilane-based organic compound is represented by a general formula “R—Si(OCH₃)₃.” The ethoxysilane-based organic compound is represented by a general formula “R—Si(OCH₂CH₃)₃.”

An example of a processing condition of step S104 is illustrated below:
HT gas flow rate: 50 sccm to 200 sccm;
Processing time: 10 seconds to 600 seconds;
Processing temperature: 80 degrees C. to 350 degrees C.; and
Processing pressure: 50 Pa to 4,000 Pa.

In addition, step S104 may include selectively forming, on the surface of the second film with respect to the surface of the first film, a film formation inhibiting film that inhibits formation of a target film. The insulating film 11 is an example of the first film, the conductive film 12 is an example of the second film, and the SAM 17 is an example of the film formation inhibiting film. The film formation inhibiting film is not limited to the SAM, and may be, for example, a graphene-containing film or a boron-containing film.

As illustrated in FIGS. 4D, 5D, and 6D, step S105 includes selectively forming a second insulating film 18 on the surface of the insulating film 11 with respect to the surface of the conductive film 12 by using the SAM 17. The second insulating film 18 is an example of a target film. The second insulating film 18 is formed by a chemical vapor deposition (CVD) method or an atomic layer deposition (ALD) method.

The second insulating film 18 is not particularly limited, but is, for example, an AlO film, a SiO film, a SiN film, a ZrO film, or a HfO film. Here, the AlO film means a film containing aluminum (Al) and oxygen (O). An atomic ratio of Al to O in the AlO film is usually 2:3, but is not limited to 2:3. Similarly, the SiO film, the SiN film, the ZrO film, and the HfO film each mean a film containing respective elements, and are not limited to a stoichiometric ratio.

From the viewpoint of lowering the k value (dielectric constant), the second insulating film 18 is desirably an oxide film such as SiO or SiOC, and more desirably a film containing SiO. The SiO film contains at least silicon (Si) and oxygen (O). The SiO film is formed, for example, by using a metal catalyst-containing gas and a silanol group-containing gas. The metal catalyst-containing gas contains a metal catalyst. The metal catalyst promotes a dehydration condensation reaction of a silanol group contained in the silanol group-containing gas. The SiO film is formed by the dehydration condensation reaction of the silanol group. The SiO film may contain the metal catalyst, in addition to silicon (Si) and oxygen (O).

The metal catalyst-containing gas is desirably an organometallic compound gas. Specifically, examples of the metal catalyst-containing gas may include an organoaluminum compound gas and an organotitanium compound gas. The organoaluminum compound gas is, for example, a trimethylaluminum (TMA) gas, a triethylaluminium (TEA) gas, a dimethylaluminum chloride gas, or a dimethylaluminum isopropoxide (DMAI) gas. The organotitanium compound gas is, for example, a tetrakis(dimethylamino)titanium (TDMAT) gas.

The silanol group-containing gas is not particularly limited, but examples thereof include tris(tert-pentoxy)silanol (TPSOL), triethylsilanol, methyl bis(tert-pentoxy)silanol, or tris(tert-butoxy)silanol (TBSOL).

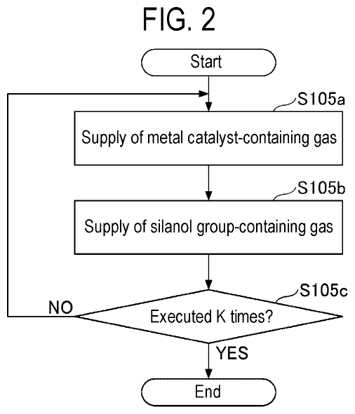

Step S105 includes, for example, supplying the metal catalyst-containing gas (step S105a) and supplying the silanol group-containing gas (step S105b), for K times (where K is an integer of 1 or more), as illustrated in FIG. 2. K may be an integer of 2 or more, and the steps S105a and S105b may be repeated multiple times. K is desirably from 1 to 5.

Step S105a includes supplying the metal catalyst-containing gas to the substrate surface 1a, thereby adsorbing the metal catalyst on the surface of the insulating film 11. The SAM 17 inhibits adsorption of the metal catalyst on the surface of the conductive film 12.

An example of a processing condition of step S105a is illustrated below:
TMA gas flow rate: 10 sccm to 100 sccm;
Processing time: 0.05 seconds to 100 seconds;
Processing temperature: 80 degrees C. to 350 degrees C.; and
Processing pressure: 133 Pa to 1,200 Pa.

Step S105b includes supplying the silanol group-containing gas to the substrate surface 1a. The metal catalyst adsorbed on the surface of the insulating film 11 promotes a dehydration condensation reaction of the silanol group contained in the silanol group-containing gas. As a result, the second insulating film 18 is selectively formed on the surface of the insulating film 11 with respect to the surface of the conductive film 12.

An example of a processing condition of step S105b is illustrated below (in addition, the TPSOL gas is supplied by vaporizing liquid TPSOL):
TPSOL gas flow rate: 0.1 g/min to 0.5 g/min;
Processing time: 3 seconds to 120 seconds;
Processing temperature: 80 degrees C. to 350 degrees C.; and
Processing pressure: 133 Pa to 1,200 Pa.

In addition, steps S105a and S105b may be carried out by supplying gases corresponding to the material of the second insulating film 18 to the substrate surface 1a. In a case where the second insulating film 18 is an AlO film, step S105a includes, for example, supplying an Al-containing gas to the substrate surface 1a, and step S105b includes, for example, supplying an oxygen-containing gas to the substrate surface 1a. The Al-containing gas is, for example, an organoaluminum compound gas. The oxygen-containing gas is, for example, a H₂O gas.

The AlO film has a slower etching rate than the SiO film in step S106. To facilitate etching of an unnecessary portion of the AlO film (a portion deposited on the surface of the conductive film 12) in step S106, it is desirable that a thickness of the AlO film formed in one step S105 be thin. A set number (K times) of step S105c may be reduced, and correspondingly, a set number (N times) of step S107 may be increased.

Step S105 may include a step of supplying a purge gas to the substrate surface 1a after the n^{th} step S105a and before the n^{th} step S105b. Further, step S105 may include a step of supplying a purge gas to the substrate surface 1a after the n^{th} step S105b and before the (n+1)^{th} step S105a. By supplying the purge gas, the gas used immediately previously may be discharged.

Meanwhile, as illustrated in FIGS. 4D, 5D, and 6D, although the SAM 17 inhibits the formation of the second insulating film 18, blocking performance of the SAM 17 is not perfect, and the second insulating film 18 may protrude laterally from the surface of the insulating film 11 and cover a part of the surface of the conductive film 12. As such, an opening width of the second insulating film 18 becomes narrower, thereby increasing a wiring resistance of the substrate 1. In particular, resistance of a via wiring penetrating between layers may increase, or a via yield may decrease. Therefore, the film forming method includes step S106.

Step S106 includes preferentially etching a part 18a of the second insulating film 18 with respect to another part 18b of the second insulating film 18. The part 18a of the second insulating film 18 includes a portion deposited on the surface of the conductive film 12, and also includes a part of the SAM 17. Therefore, the part 18a of the second insulating film 18 has more defects and has a faster etching rate than the another part 18b of the second insulating film 18.

Even when, instead of the SAM 17, a graphene-containing film or a boron-containing film is formed as a film formation inhibiting film that inhibits the formation of the second insulating film 18 in step S104, the part 18a of the second insulating film 18 has a faster etching rate than the another part 18b of the second insulating film 18. This is because the second insulating film in the vicinity of the film formation inhibiting film (the part 18a of the second insulating film 18) has inhibited growth due to influence of the film formation inhibiting film, resulting in thinning or reduced density.

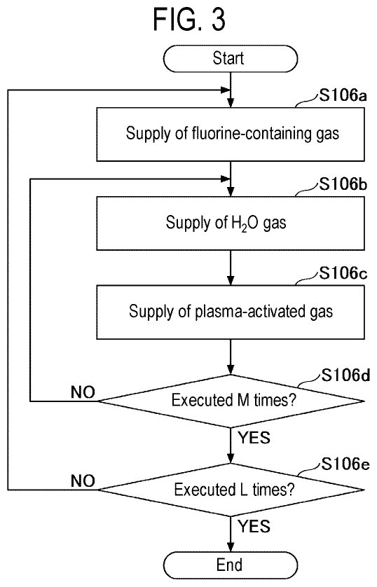

As illustrated in FIG. 3, step S106 includes, for example, supplying a fluorine-containing gas (step S106a), supplying a H₂O gas (step S106b), and supplying a plasma-activated gas (step S106c). Step S106 includes performing steps S106b and S106c a set number of times (M times). M may be an integer of 2 or more, and steps S106b to S106c may be repeated multiple times. Further, step S106 includes performing step S106a once and performing steps S106b and S106c M times, for a set number of times (L times). L may be an integer of 2 or more, and steps S106a to S106c may be repeated multiple times.

As illustrated in FIGS. 4E, 5E, and 6E, step S106a includes forming a fluorine-containing layer 19 on the surface of the second insulating film 18 by supplying a fluorine-containing gas to the surface of the second insulating film 18. The fluorine-containing layer 19 may be deposited not only on the surface of the second insulating film 18, but also on the surface of the SAM 17. In addition, fluorine may be adsorbed on the surface of the second insulating film 18, instead of forming the fluorine-containing layer 19 on the surface of the second insulating film 18.

The fluorine-containing gas is, for example, a mixed gas of a HF gas and a NH₃ gas. The fluorine-containing layer 19 is formed by a reaction of the mixed gas of the HF gas and the NH₃ gas with the second insulating film 18. In a case where the second insulating film 18 is a film containing silicon (Si) and oxygen (O), the fluorine-containing layer 19 contains ammonium fluorosilicate ((NH₄)₂SiF₆).

The fluorine-containing layer 19 only needs to be formed such that an unnecessary portion of the second insulating film 18 (a portion deposited on the surface of the conductive film 12) may be etched in steps S106b and S106c. To adjust an amount of formation of the fluorine-containing layer 19, it is desirable that step S106a be performed at a lower temperature than steps S106b and S106c. A temperature of the substrate 1 in step S106a is, for example, 50 degrees C. to 100 degrees C.

In addition, although the fluorine-containing gas is the mixed gas of the HF gas and the NH₃ gas in the present embodiment, it may not include the NH₃ gas, and may only include the HF gas. In this case, fluorine may be adsorbed on the surface of the second insulating film 18, instead of forming the fluorine-containing layer 19 on the surface of the second insulating film 18.

An example of a processing condition of step S106a is illustrated below:
HF gas flow rate: 10 sccm to 100 sccm;
NH₃ gas flow rate: 10 sccm to 100 sccm;
Processing time: 0.05 seconds to 100 seconds;
Processing temperature: 30 degrees C. to 150 degrees C. (desirably 30 degrees C. to 100 degrees C., more desirably 50 degrees C. to 100 degrees C.); and
Processing pressure: 50 Pa to 1,200 Pa.

Step S106b includes supplying a H₂O gas to the surface of the second insulating film 18 to generate a hydrogen fluoride. The hydrogen fluoride is generated by a reaction between the fluorine-containing layer 19 and the H₂O gas. In addition, the hydrogen fluoride may also be generated by a reaction between the fluorine adsorbed on the surface of the second insulating film 18, instead of the fluorine-containing layer 19, and the H₂O gas. In step S106b, a H₂O₂ gas may be used in addition to the H₂O gas. It is desirable not to plasma-activate the H₂O gas in step S106b. This makes it possible to prevent generation of oxygen plasma, thereby preventing oxidation of the conductive film 12.

An example of a processing condition of step S106b is illustrated below:
H₂O gas flow rate: 10 sccm to 500 sccm;
Processing time: 0.1 seconds to 120 seconds;
Processing temperature: 80 degrees C. to 350 degrees C.; and
Processing pressure: 50 Pa to 1,200 Pa.

Step S106c includes supplying a plasma-activated gas to the surface of the second insulating film 18. By sequentially performing step S106b and step S106c, plasma activation of the H₂O gas may be prevented, oxygen plasma generation may be prevented, and oxidation of the conductive film 12 may be prevented.

In step S106c, it is desirable that a gas to be plasma-activated does not include an oxygen-based gas, so as to prevent oxygen plasma generation. The gas to be plasma-activated is, for example, a H₂ gas, a noble gas, or a mixed gas of the H₂ gas and the noble gas. The noble gas is, for example, an Ar gas or a He gas. Plasma promotes decomposition of the fluorine-containing layer 19 or desorption of fluorine, thereby promoting generation of hydrogen fluoride. Thereby, etching of the second insulating film 18 by the hydrogen fluoride may be promoted.

According to the present embodiment, the part 18a of the second insulating film 18 is preferentially etched with respect to the another part 18b of the second insulating film 18. An unnecessary portion of the second insulating film 18 (a portion deposited on the surface of the conductive film 12) is etched, whereas a necessary portion of the second insulating film 18 (a portion deposited on the surface of the insulating film 11) is hardly etched. Therefore, it is possible to selectively remove the unnecessary portion of the second insulating film 18.

An example of a processing condition of step S106c is illustrated below:
H₂ gas flow rate: 200 sccm to 3,000 sccm;
Ar gas flow rate: 100 sccm to 6,000 sccm;
Proportion of H₂ gas in the mixed gas of H₂ gas and Ar gas: 0 vol % to 90 vol %;
Power supply frequency for plasma generation: 10 MHz to 60 MHz;
Power for plasma generation: 50 W to 600 W;
Processing time: 2 seconds to 120 seconds;
Processing temperature: 80 degrees C. to 350 degrees C.; and
Processing pressure: 50 Pa to 1,200 Pa.

Although not illustrated, step S106c desirably includes, in a desired order, plasma-activating and supplying a H₂ gas alone or a mixed gas of the H₂ gas and a noble gas to the surface of the second insulating film 18 (step S106c1), and plasma-activating and supplying the noble gas alone to the surface of the second insulating film 18 (step S106c2). The order may be either way, but step S106c2 may be performed after step S106c1.

As will be described in detail in the Examples section, a leakage current of the second insulating film 18 remaining after step S106c is reduced by including steps S106cl and S106c2 in step S106c. In addition, although step S106cl may plasma-activate the H₂ gas alone and supply the same to the surface of the second insulating film 18 as described above, it is desirable to plasma-activate the mixed gas of the H₂ gas and the noble gas and supply the same to the surface of the second insulating film 18, from the viewpoint of promoting plasma generation.

Step S106d includes checking whether steps S106b and S106c have been executed a set number of times (M times). In a case where the number of executions has not reached the set number of times (M times), the etching of the second insulating film 18 is insufficient, such that steps S106b and S106c are executed again. On the other hand, in a case where the number of executions has reached the set number of times (M times), the etching of the second insulating film 18 is sufficient, such that subsequent processing from step S106e onward is performed.

The set number of times (M times) in step S106d is, for example, from 1 to 50 times, desirably from 2 to 50 times. In a case where M is an integer of 2 or more, steps S106b and S106c are repeated multiple times. The decomposition of the fluorine-containing layer 19 or the desorption of fluorine may thereby be gradually progressed, and the hydrogen fluoride may be generated over a long time. As a result, the opening width of the second insulating film 18 may be expanded, thereby enabling a reduction in the wiring resistance of the substrate 1.

Step S106e includes checking whether performing step S106a once and steps S106b and S106c M times has been performed a set number of times (L times). In a case where the number of executions has not reached the set number of times (L times), the etching of the second insulating film 18 is insufficient, such that steps S106a to S106c are executed again. On the other hand, in a case where the number of executions has reached the set number of times (L times), the etching of the second insulating film 18 is sufficient, such that subsequent processing from step S107 onward is performed.

The set number of times (L times) in step S106e is, for example, from 1 to 50 times, desirably from 2 to 50 times. In a case where L is an integer of 2 or more, steps S106a to S106c are repeated multiple times. Since the fluorine-containing layer 19 can be regenerated, the hydrogen fluoride can be generated over a long time. As a result, the opening width of the second insulating film 18 may be expanded, resulting in a reduction in the wiring resistance of the substrate 1.

Step S107 includes checking whether steps S104 to S106 have been executed a set number of times (N times). In a case where the number of executions has not reached the set number of times, the thickness of the second insulating film 18 has not reached a target film thickness, such that steps S104 to S106 are executed again. On the other hand, in a case where the number of executions has reached the set number of times, a thickness of the second insulating film 18 has reached the target film thickness, such that the present processing is terminated.

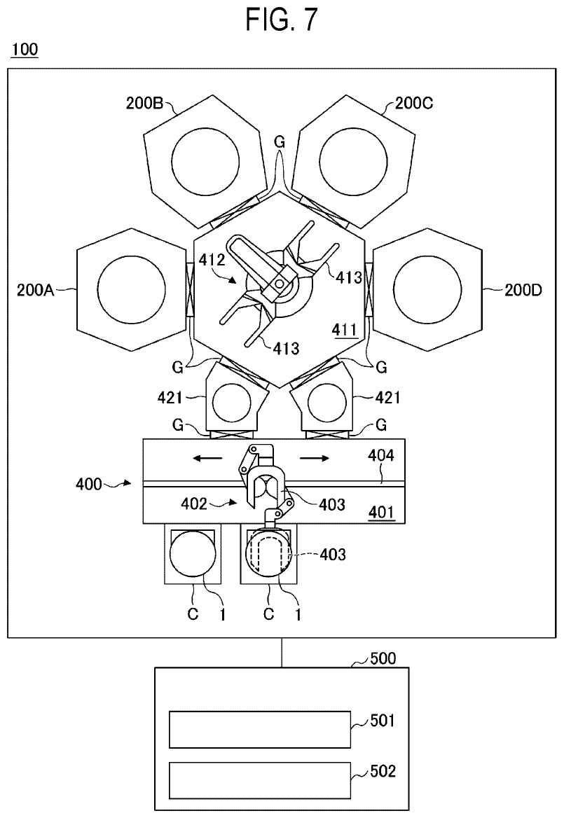

Next, a film forming apparatus 100 that performs the film forming method will be described with reference to FIG. 7. As illustrated in FIG. 7, the film forming apparatus 100 includes a first processing section 200A, a second processing section 200B, a third processing section 200C, a fourth processing section 200D, a transport section 400, and a controller 500. The first processing section 200A performs steps S102 and S103 in FIG. 1. The second processing section 200B performs step S104 in FIG. 1. The third processing section 200C performs step S105 in FIG. 1. The fourth processing section 200D performs step S106 in FIG. 1. The first processing section 200A, the second processing section 200B, the third processing section 200C, and the fourth processing section 200D may have the same structure or different structures. It is also possible for only the first processing section 200A to perform all steps S102 to S106 in FIG. 1. The transport section 400 transports the substrate 1 to and from the first processing section 200A, the second processing section 200B, the third processing section 200C, and the fourth processing section 200D. The controller 500 controls the first processing section 200A, the second processing section 200B, the third processing section 200C, the fourth processing section 200D, and the transport section 400.

The transport section 400 includes a first transport chamber 401 and a first transport mechanism 402. An internal atmosphere of the first transport chamber 401 is an atmospheric atmosphere. The first transport mechanism 402 is provided in the interior of the first transport chamber 401. The first transport mechanism 402 includes an arm 403 that holds the substrate 1, and travels along a rail 404. The rail 404 extends in a direction in which carriers C are arranged.

Further, the transport section 400 includes a second transport chamber 411 and a second transport mechanism 412. An internal atmosphere of the second transport chamber 411 is a vacuum atmosphere. The second transport mechanism 412 is provided in the second transport chamber 411. The second transport mechanism 412 includes an arm 413 that holds the substrate 1, and the arm 413 is arranged to be movable in vertical and horizontal directions and to be rotatable about a vertical axis. The first processing section 200A, the second processing section 200B, the third processing section 200C, and the fourth processing section 200D are connected to the second transport chamber 411 via different gate valves G.

Additionally, the transport section 400 includes a load lock chamber 421 between the first transport chamber 401 and the second transport chamber 411. An internal atmosphere of the load lock chamber 421 is switched between a vacuum atmosphere and an atmospheric atmosphere by a pressure regulating mechanism (not illustrated). Thereby, the interior of the second transport chamber 411 may always be maintained in a vacuum atmosphere. Further, a flow of a gas from the first transport chamber 401 into the second transport chamber 411 may be prevented. Gate valves G are provided between the first transport chamber 401 and the load lock chamber 421 and between the second transport chamber 411 and the load lock chamber 421.

The controller 500 is, for example, a computer, and includes a processor 501 such as a central processing unit (CPU) and a storage 502 such as a memory. The storage 502 stores a program for controlling various types of processing executed in the film forming apparatus 100. The controller 500 controls the operation of the film forming apparatus 100 by causing the processor 501 to execute the program stored in the storage 502. The controller 500 controls the first processing section 200A, the second processing section 200B, the third processing section 200C, the fourth processing section 200D, and the transport section 400 to execute the film forming method.

The controller 500 includes an electronic circuit such as a CPU, field programmable gate array (FPGA) or application specific integrated circuit (ASIC), and executes various control operations described in the present disclosure by executing instruction codes stored in a memory or by being circuit-designed for a specific application.

Next, the operation of the film forming apparatus 100 will be described. First, the first transport mechanism 402 takes out the substrate 1 from the carrier C, transports the taken-out substrate 1 to the load lock chamber 421, and discharges the same from the load lock chamber 421. Subsequently, an internal atmosphere of the load lock chamber 421 is switched from an atmospheric atmosphere to a vacuum atmosphere. Thereafter, the second transport mechanism 412 takes out the substrate 1 from the load lock chamber 421, and transports the taken-out substrate 1 to the first processing section 200A.

Subsequently, the first processing section 200A performs steps S102 and S103. Thereafter, the second transport mechanism 412 takes out the substrate 1 from the first processing section 200A, and transports the taken-out substrate 1 to the second processing section 200B. During this time, the atmosphere around the substrate 1 may be maintained in a vacuum atmosphere, which may prevent unintended oxidation of the substrate 1.

Subsequently, the second processing section 200B performs step S104. Thereafter, the second transport mechanism 412 takes out the substrate 1 from the second processing section 200B, and transports the taken-out substrate 1 to the third processing section 200C. During this time, the atmosphere around the substrate 1 may be maintained in a vacuum atmosphere, which may prevent deterioration in the blocking performance of the SAM 17.

Subsequently, the third processing section 200C performs step S105. Thereafter, the second transport mechanism 412 takes out the substrate 1 from the third processing section 200C, and transports the taken-out substrate 1 to the fourth processing section 200D. During this time, the atmosphere around the substrate 1 may be maintained in a vacuum atmosphere, which may prevent unintended oxidation of the substrate 1.

Subsequently, the fourth processing section 200D performs step S106. Thereafter, the controller 500 checks whether steps S104 to S106 have been executed a set number of times (N times). In a case where the number of executions has not reached the set number of times, the second transport mechanism 412 takes out the substrate 1 from the fourth processing section 200D, and transports the taken-out substrate 1 to the second processing section 200B. Thereafter, the controller 500 controls the second processing section 200B, the third processing section 200C, the fourth processing section 200D, and the transport section 400 to execute steps S104 to S106 again.

On the other hand, in a case where the number of executions has reached the set number of times, the second transport mechanism 412 takes out the substrate 1 from the fourth processing section 200D, transports the taken-out substrate 1 to the load lock chamber 421, and discharges the same from the load lock chamber 421. Subsequently, the internal atmosphere of the load lock chamber 421 is switched from a vacuum atmosphere to an atmospheric atmosphere. Thereafter, the first transport mechanism 402 takes out the substrate 1 from the load lock chamber 421, and accommodates the taken-out substrate 1 in the carrier C. Then, the processing of the substrate is terminated.

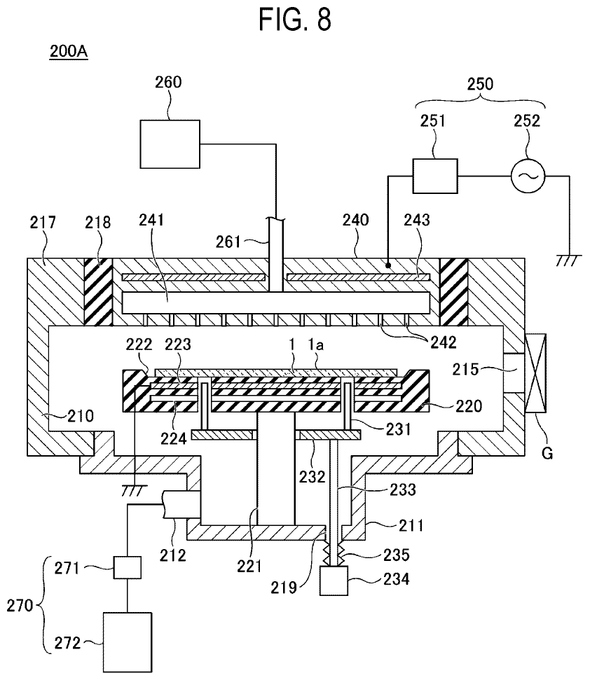

Next, the first processing section 200A will be described with reference to FIG. 8. In addition, since the second processing section 200B, the third processing section 200C, and the fourth processing section 200D are configured in the same manner as the first processing section 200A, illustration and description thereof will be omitted.

The first processing section 200A includes a substantially cylindrical airtight processing container 210. An exhaust chamber 211 is provided in a bottom wall central portion of the processing container 210. The exhaust chamber 211 has, for example, a substantially cylindrical shape that protrudes downward. An exhaust pipe 212 is connected to the exhaust chamber 211, for example, at the lateral side of the exhaust chamber 211.

An exhaust source 272 is connected to the exhaust pipe 212 via a pressure controller 271. The pressure controller 271 includes, for example, a pressure adjustment valve such as a butterfly valve. The exhaust pipe 212 is configured to decompress the interior of the processing container 210 by using the exhaust source 272. The pressure controller 271 and the exhaust source 272 constitute a gas discharge mechanism 270 that discharges gases inside the processing container 210.

A transport port 215 is provided at the lateral side of the processing container 210. The transport port 215 is opened or closed by the gate valve G. The loading and unloading of the substrate 1 between the interior of the processing container 210 and the second transport chamber 411 (see FIG. 7) are achieved through the transport port 215.

A stage 220 which is a holder for holding the substrate 1 is provided inside the processing container 210. The stage 220 holds the substrate 1 horizontally with the substrate surface 1a facing upward. The stage 220 is formed in a substantially circular shape in a plan view, and is supported by a support member 221. A substantially circular recess 222 is formed on the surface of the stage 220 for placing the substrate 1 having a diameter of 300 mm, for example. The recess 222 has an inner diameter slightly larger than the diameter of the substrate 1. The recess 222 is configured, for example, to have a depth substantially the same as the thickness of the substrate 1. The stage 220 is formed of a ceramic material such as aluminum nitride (AlN), for example. Further, the stage 220 may be formed of a metallic material such as nickel (Ni). In addition, instead of the recess 222, a guide ring for guiding the substrate 1 may be provided on the peripheral edge of the surface of the stage 220.

For example, a grounded lower electrode 223 is embedded in the stage 220. A heating mechanism 224 is embedded below the lower electrode 223. The heating mechanism 224 heats the substrate 1 placed on the stage 220 to a set temperature upon receiving power supplied from a power supply (not illustrated) based on a control signal from the controller 500 (see FIG. 7). In a case where the stage 220 is entirely formed of a metal, the entire stage 220 functions as a lower electrode, such that the lower electrode 223 may not be embedded in the stage 220. The stage 220 is provided with a plurality of (for example, three) lifting pins 231 for holding and vertically moving the substrate 1 placed on the stage 220. The material of the lifting pins 231 may be, for example, ceramics such as alumina (Al₂O₃) or quartz. The lower ends of the lifting pins 231 are attached to a support plate 232. The support plate 232 is connected to a lifting mechanism 234 provided outside the processing container 210 via a lifting shaft 233.

The lifting mechanism 234 is provided, for example, beneath the exhaust chamber 211. A bellows 235 is provided between the lifting mechanism 234 and an opening 219 for the lifting shaft 233 formed in the lower surface of the exhaust chamber 211. The support plate 232 may be formed in a shape that allows the support plate 232 to vertically move without interfering with the support member 221 of the stage 220. The lifting pins 231 are configured to be vertically movable between above the surface of the stage 220 and below the surface of the stage 220 by the lifting mechanism 234.

A gas supplier 240 is provided on a ceiling wall 217 of the processing container 210 via an insulating member 218. The gas supplier 240 forms an upper electrode and is opposite to the lower electrode 223. A radio frequency power supply 252 is connected to the gas supplier 240 via a matcher 251. By supplying radio frequency power in the range of 450 kHz to 100 MHz from the radio frequency power supply 252 to the upper electrode (gas supplier 240), a radio frequency electric field is generated between the upper electrode (gas supplier 240) and the lower electrode 223, producing a capacitively coupled plasma. A plasma generator 250 that generates a plasma includes the matcher 251 and the radio frequency power supply 252. In addition, the plasma generator 250 is not limited to generating the capacitively coupled plasma, but may also generate other types of plasma such as inductively coupled plasma. In addition, in steps that do not generate a plasma (for example, steps S104 and S105), it is unnecessary for the gas supplier 240 to form the upper electrode, and the lower electrode 223 is also not necessary.

The gas supplier 240 includes a hollow gas supply chamber 241. A large number of holes 242 for dispersing and supplying a processing gas into the processing container 210 are evenly arranged, for example, at the lower surface of the gas supply chamber 241. A heating mechanism 243 is embedded above, for example, the gas supply chamber 241 in the gas supplier 240. The heating mechanism 243 is heated to a set temperature upon receiving power from a power supply (not illustrated) based on a control signal from the controller 500.

A gas supply mechanism 260 is connected to the gas supply chamber 241 through a gas supply path 261. The gas supply mechanism 260 supplies gases used in at least one selected from the group of steps S102 to S106 in FIG. 1 to the gas supply chamber 241 through the gas supply path 261. The gas supply mechanism 260 includes, although not illustrated, an individual pipe for each gas type, an on-off valve provided in the middle of the individual pipe, and a flow-rate controller provided in the middle of the individual pipe. When the on-off valve opens the individual pipe, a gas is supplied from a supply source to the gas supply path 261. A supply amount of gas is controlled by the flow-rate controller. On the other hand, when the on-off valve closes the individual pipe, the supply of gas from the supply source to the gas supply path 261 is stopped.

### Examples

Next, experimental data will be described. First, Examples 1 to 6 will be described with reference to Table 1. In Examples 1 to 6, a substrate having a Low-k film and a Cu film in different regions of the substrate surface was prepared, and the substrate was processed under a condition illustrated in Table 1. Examples 1 and 2 are comparative examples, and Examples 3 to 6 are embodiments.

TABLE 1

| | | Example | Example | Example | Example | Example | Example |
|---|---|---|---|---|---|---|---|
| | | 1 | 2 | 3 | 4 | 5 | 6 |
| Condition | S102 | plasma (H₂ + N₂): 15 s, O₂: 30 s, PFBA | | | | | |
| | S103 | plasma (H₂ + Ar): 30 s | | | | | |
| | S104 | HT: 60 s | | | | | |
| | S105a | TMA: 10 s | | | | | |
| | S105b | TPSOL: 15 s | | | | | |
| | S105c | K = 1 | | | | | |
| | S106a | None | | HF: 60s | | (HF + NH₃): 7 s | |
| | S106b | H₂O: 10 s | | | | | |
| | S106c | plasma (H₂ + Ar): 30 s | | | | | |
| | S106d | M = 6 | | M = 3 | | | |
| | S107 | N = 1 | N = 2 | N = 1 | N = 2 | N = 1 | N = 3 |
| SiO | Film | 6.6 | 12.7 | 7.2 | 13.1 | 5.1 | 12.3 |
| Film | thickness | | | | | | |
| | [nm] | | | | | | |
| | Opening | 12.62 | — | 13.03 | — | 17.34 | 12.42 |
| | width | | | | | | |
| | [nm] | | | | | | |

In Examples 1 to 6, steps S102 to S5105 were set to the same condition. In step S5102, a mixed gas of a H₂ gas and a N₂ gas was plasma-activated and supplied for 15 seconds, then an O₂ gas was supplied for 30 seconds, and then a PFBA gas was supplied. In step S103, a mixed gas of the H₂ gas and an Ar gas was plasma-activated and supplied for 30 seconds. In step S104, an SAM was selectively formed on the surface of the Cu film by supplying a HT gas for 60 seconds. In step S105, a SiO film was selectively formed on the surface of the Low-k film by supplying a TMA gas for 10 seconds and then supplying a TPSOL gas for 15 seconds.

In Example 1, after steps S102 to S105, steps S106b and S106c were repeated six times without performing step S106a. In step S106b, an H₂O gas was supplied for 10 seconds. In step S106c, a mixed gas of an H₂ gas and an Ar gas was plasma-activated and supplied for 30 seconds. In Example 1, the set number of times (M times) in step S106d was six, and the set number of times (N times) in step S107 was one. In addition, since step S106a was not performed, the set number of times (L times) in step S106e was zero.

In Example 2, except that the set number of times (N times) in step S107 was two, after steps S102 to S105, steps S106b and S106c were repeated six times without performing step S106a, as in Example 1.

In Example 3, after steps S102 to S105, step S106a was performed, followed by steps S106b and S106c being repeated three times. In step S106a, an HF gas was supplied for 60 seconds. In Example 3, the set number of times (M times) in step S106d was three, the set number of times (L times) in step S106e was one, and the set number of times (N times) in step S107 was one.

In Example 4, except that the set number of times (N times) in step S107 was two, step S106a was performed after steps S102 to S105, followed by steps S106b and S106c being repeated three times, as in Example 3.

In Example 5, after steps S102 to S105, step S106a was performed, followed by steps S106b and S106c being repeated three times. In step S106a, a mixed gas of a HF gas and a NH₃ gas was supplied for 7 seconds. In Example 5, the set number of times (M times) in step S106d was three, the set number of times (L times) in step S106e was one, and the set number of times (N times) in step S107 was one.

In Example 6, except that the set number of times (N times) in step S107 was three, after steps S102 to S105, step S106a was performed, followed by steps S106b and S106c being repeated three times, as in Example 5.

In addition, the set number of times (N times) in step S107 was set to three in Example 6, so as to make a thickness of the SiO film obtained in Example 6 approximately the same as thicknesses of the SiO films obtained in Examples 2 and 4.

As is apparent from comparing the opening widths of the SiO films obtained in Examples 1, 3, and 5 in Table 1, it can be seen that the opening width of the SiO film may be increased by performing all of steps S106a, S106b, and S106c.

Also, as is apparent from comparing the opening widths of the SiO films obtained in Examples 3 and 5 in Table 1, it can be seen that by using a mixed gas of a HF gas and a NH₃ gas in step S106a, the opening width of the SiO film may be increased compared to the case of using only the HF gas in step S106a.

Next, Examples 7 to 9 will be described with reference to Table 2. In Examples 7 to 9, a substrate having a SiO film (film thickness: 8.0 nm) formed over the entire surface of a silicon wafer was prepared, and etching of the SiO film was performed under a condition illustrated in Table 2. Examples 7 to 9 are reference examples. In addition, the set number of times (L times) in step S106e was zero in Example 7 and one in Examples 8 and 9. The SiO film was formed by supplying a TMA gas and a TPSOL gas in this order to the surface of the silicon wafer. The SiO film was a dense film free of SAM contamination.

TABLE 2

| | | Example 7 | Example 8 | Example 9 |
|---|---|---|---|---|
| Condition | S106a | None | (HF + NH₃): 30 s | |
| | S106b | H₂O: 10 s | None | H₂O: 10 s |
| | S106c | plasma (H₂ + Ar): 30 s | | |
| | S106d | M = 3 | | |
| SiO | Film thickness | 7.5 | 4.7 | 2.7 |
| Film | [nm] | | | |
| | Etching amount | 0.5 | 3.3 | 5.3 |
| | [nm] | | | |

In Table 2, the etching amount is a change in the thickness of the SiO film. From Table 2, it can be seen that the etching amount of the SiO film may be increased by performing all of steps S106a, S106b, and S106c.

Next, Examples 10 to 13 will be described with reference to Table 3. In Examples 10 to 13, a substrate having a SiO film (film thickness: 5.3 nm) formed over the entire surface of a silicon wafer was prepared, and etching of the SiO film was performed under a condition illustrated in Table 3. Examples 10 to 13 are reference examples. In addition, the set number of times (L times) in step S106e was one. The SiO film was formed by supplying a TMA gas and a TPSOL gas in this order to the surface of the silicon wafer. The SiO film was a dense film free of SAM contamination. In Examples 11 and 13, unlike Examples 10 and 12, modification of the SiO film was performed after the formation of the SiO film (step S105) and before the etching of the SiO film (step S106). The modification of the SiO film was performed by using a plasma-activated mixed gas of a H₂ gas and an Ar gas.

TABLE 3

| | | Example 10, | Example 12, |
|---|---|---|---|
| | | Example 11 | Example 13 |
| Condition | S106a | HF | HF + NH₃ |

| | |
|---|---|
| S106b | H₂O: 10 s |
| S106c | plasma (H₂ + Ar): 30 s |
| S106d | M = 3 |

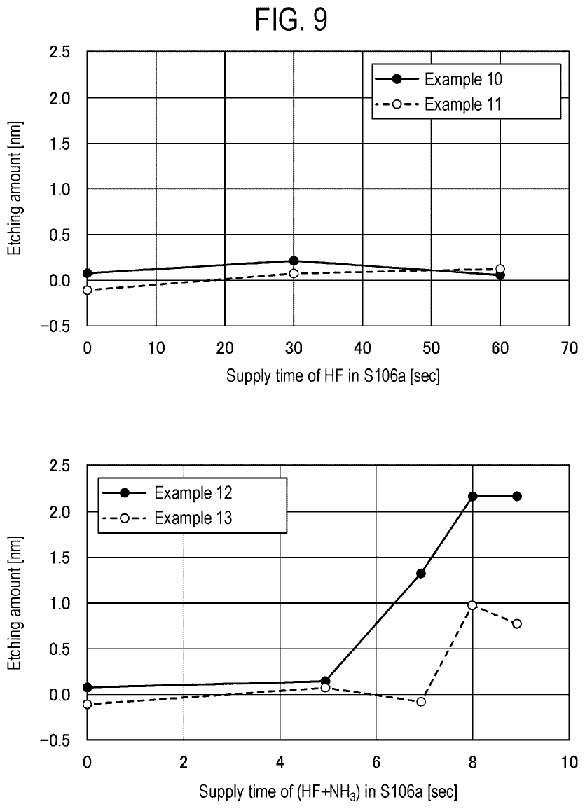

In Examples 10 to 13, the etching of a SiO film (step S106) was performed under the same condition, except for the type of gas and the gas supply time in S106a. FIG. 9 illustrates a relationship between the gas supply time and the etching amount in S106a of Examples 10 to 13. In addition, in FIG. 9, the fact that the etching amount of some data is slightly negative is due to measurement errors.

From FIG. 9, it can be seen that, in a case where only the HF gas was used in S106a, a necessary portion of the SiO film (a portion free of SAM contamination) tends to remain for a long time, as compared with a case where the mixed gas of the HF gas and the NH₃ gas is used in S106a. Further, it can be seen that, even in a case where the mixed gas of the HF gas and the NH₃ gas is used in S106a, a necessary portion of the SiO film (a portion free of SAM contamination) mostly remains when the supply time of the mixed gas is short.

In addition, in a case where the mixed gas of the HF gas and the NH₃ gas is used in S106a, the supply time of the mixed gas may be long. It is sufficient that a necessary portion of the SiO film (a portion free of SAM contamination) remains even slightly after S106. An etching rate of a necessary portion of the SiO film is slower than an etching rate of an unnecessary portion of the SiO film (a portion contaminated with SAM). Therefore, even in a case where the mixed gas of the HF gas and the NH₃ gas is used in S106a, it is possible to leave a necessary portion of the SiO film.

Next, Examples 14 and 15 will be described with reference to Table 4. In Examples 14 and 15, a silicon wafer was prepared, and the silicon wafer was processed under a condition illustrated in Table 4. Examples 14 and 15 are reference examples. In addition, the set number of times (L times) in step S106e was one. A SiO film was formed by supplying a TMA gas and a TPSOL gas in this order to the surface of the silicon wafer. The SiO film was a dense film free of SAM contamination. In Example 15, unlike Example 14, in step S106c, a step of plasma-activating and supplying a mixed gas of a H₂ gas and a noble gas to the surface of the second insulating film 18 (step S106c1), and a step of plasma-activating and supplying a noble gas alone to the surface of the second insulating film 18 (step S106c2) were performed in this order.

TABLE 4

| | | Example 14 | Example 15 |
|---|---|---|---|
| Condition | S102 | plasma (H₂ + N₂): 15 s, Acetic acid: 300 s | |
| | S103 | plasma (H₂ + Ar): 30 s | |
| | S104 | HT: 60 s | |
| | S105a | TMA: 10 s | |
| | S105b | TPSOL: 4.8 s(1^{th} time), 10 s(2^{nd} time), 6 s(3^{rd} time) | |
| | S105c | K = 1 | |
| | S106a | (HF + NH₃): 7 s(1^{th} time, 2^{nd} time), 9 s(3^{rd} time) | |
| | S106b | H₂O: 10 s | |
| | S106c | plasma (H₂ + Ar): 30 s | plasma (H₂ + Ar): 10 s |
| | | | plasma Ar: 20 s |
| | S106d | M = 3 | |
| | S107 | N = 3 | |
| SiO | Film thickness | 7.5 | 8.4 |
| Film | [nm] | | |
| | Leakage current | — | 1.01 |
| | @5 MV | (5 MV Under) | |
| | [×10⁻⁷ A/cm] | | |

In Examples 14 and 15, the etching of the SiO film (step S106) was performed under the same condition, except for the type of gas and the gas supply time in S106c. As a result, the SiO film remained in both Examples 14 and 15. However, when a voltage was applied in the thickness direction of the SiO film so as to measure the leakage current of the SiO film, in Example 14, a large amount of current flowed, and the voltage did not reach 5 MV. On the other hand, in Example 15, the leakage current at the time when the voltage reached 5 MV was minute.

From this, it can be seen that a film quality of the SiO film may be improved by performing S106cl1 and S106c2 in S106c.

Next, Examples 16 and 17 will be described with reference to Table 5. In Examples 16 and 17, a substrate having a Low-k film and a Co film in different regions of the substrate surface was prepared, and the substrate was processed under a condition illustrated in Table 5. Example 16 is an embodiment, and Example 17 is a comparative example.

TABLE 5

| | | Example 16 | Example 17 |
|---|---|---|---|
| Condition | S102 | plasma (H₂ + N₂): 15 s, Acetic acid: 300 s | |
| | S103 | plasma (H₂ + Ar): 30 s | |
| | S104 | HT: 300 s | |
| | S105a | TMA: 0.5 s | |
| | S105b | H₂O: 1.0 s | |
| | S105c | K = 15 | K = 45 |
| | S106a | (HF + NH₃): 30 s | None |
| | S106b | H₂O: 10 s | |
| | S106c | plasma (H₂ + Ar): 10 s | |
| | | plasma Ar: 20 s | |
| | S106d | M = 3 | |
| | S107 | N = 3 | N = 1 |

| | | |
|---|---|---|
| Presence/absence of | 7.5 | 8.4 |
| AlO film on Co film | None | Present |

In Examples 16 and 17, steps S102 to S104 were set to the same condition. In step S102, a mixed gas of a H₂ gas and a N₂ gas was plasma-activated and supplied for 15 seconds, and then an acetic acid gas was supplied for 300 seconds. In step S103, a mixed gas of a H₂ gas and an Ar gas was plasma-activated and supplied for 30 seconds. In step S104, a SAM was selectively formed on the surface of the Co film by supplying a HT gas for 300 seconds.

In Examples 16 and 17, step S105 was set to the same condition, except for the set number of times (K times) in step S105c. In step S105, an AlO film was selectively formed on the surface of the Low-k film by repeatedly supplying a TMA gas for 0.5 seconds and then supplying a H₂O gas for 1.0 second multiple times. The K in Example 16 was one-third of the K in Example 17. In addition, since N in Example 16 was three times N in Example 17, a total number of executions of step S105 was the same in Examples 16 and 17.

In Example 16, after steps S102 to S105, step S106a was performed, followed by steps S106b and S106c being repeated three times. In step S106a, a mixed gas of a HF gas and a NH₃ gas was supplied for 30 seconds. In step S106b, a H₂O gas was supplied for 10 seconds. In step S106c, a mixed gas of a H₂ gas and an Ar gas was plasma-activated and supplied for 10 seconds, and then an Ar gas alone was plasma-activated and supplied for 20 seconds. In Example 16, the set number of times (M times) in step S106d was three, and the set number of times (L times) in step S106e was one.

In Example 17, after steps S102 to S105, steps S106b and S106c were repeated three times without performing step S106a. In Example 17, steps S106b and S106c were performed under the same condition as in Example 16. In Example 17, the set number of times (M times) in step S106d was three, and the set number of times (L times) in step S106e was one.

As illustrated in Table 5, in Example 16, unlike Example 17, the AlO film on the Co film could be removed by performing all of steps S106a, S106b, and S106c.

Although the embodiments of the film forming method and the film forming apparatus according to the present disclosure have been described above, the present disclosure is not limited to the above embodiments. Various changes, modifications, substitutions, additions, deletions, and combinations are possible within the scope set forth in the claims. These also naturally belong to the technical scope of the present disclosure.

According to one aspect of the present disclosure, it is possible to preferentially etch a part of a target film with respect to another part of the target film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
(A) preparing a substrate having a first film and a second film formed of a material different from that of the first film on different regions of a surface of the substrate;
(B) selectively forming a film formation inhibiting film that inhibits formation of a target film on a surface of the second film with respect to a surface of the first film;
(C) selectively forming the target film on the surface of the first film with respect to the surface of the second film by using the film formation inhibiting film; and
(D) preferentially etching a part of the target film with respect to another part of the target film,
wherein (D) includes:
(Da) supplying a fluorine-containing gas to a surface of the target film to adsorb fluorine on the surface of the target film, or to form a fluorine-containing layer on the surface of the target film;
(Db) after (Da), supplying a H₂O gas to the surface of the target film to generate hydrogen fluoride; and
(Dc) after (Db), supplying a plasma-activated gas to the surface of the target film.

2. The film forming method of claim 1, wherein the part of the target film preferentially etched in (D) includes a portion deposited on the surface of the second film.

3. The film forming method of claim 1, wherein (Db) and (Dc) in (D) are repeated a plurality of times.

4. The film forming method of claim 3, wherein (Da), (Db), and (Dc) in (D) are repeated a plurality of times.

5. The film forming method of claim 1, wherein (B), (C), and (D) are repeated a plurality of times.

6. The film forming method of claim 1, wherein the first film is an insulating film, and the second film is a conductive film.

7. The film forming method of claim 1, wherein the film formation inhibiting film is a self-assembled monolayer.

8. The film forming method of claim 1, wherein the film formation inhibiting film is a graphene-containing film.

9. The film forming method of claim 1, wherein the film formation inhibiting film is a boron-containing film.

10. The film forming method of claim 1, wherein the target film is an oxide film.

11. The film forming method of claim 10, wherein the target film is a film containing silicon (Si) and oxygen (O).

12. The film forming method of claim 10, wherein the target film is a film containing aluminum (Al) and oxygen (O).

13. The film forming method of claim 1, wherein the fluorine-containing gas is a mixed gas of a HF gas and a NH₃ gas.

14. The film forming method of claim 1, wherein the plasma-activated gas in (Dc) includes a H₂ gas, a noble gas, or a mixed gas of the H₂ gas and the noble gas.

15. The film forming method of claim 14, wherein (Dc) includes plasma-activating and supplying either only the H₂ gas or the mixed gas of the H₂ gas and the noble gas to the surface of the target film, and plasma-activating and supplying only the noble gas to the surface of the target film in a desired order.

16. A film forming apparatus comprising:
a processing container;
a holder configured to hold a substrate in the processing container;
a gas supply mechanism configured to supply a gas to into the processing container;
a plasma generator configured to plasma-activate the gas supplied into the processing container;
a gas discharge mechanism configured to discharge the gas from an interior of the processing container;
a transport mechanism configured to load or unload the substrate into or from the processing container; and
a controller configured to control the gas supply mechanism, the plasma generator, the gas discharge mechanism, and the transport mechanism, so as to perform the film forming method of claim 1.
